(19) United States
(12) Patent Application Publication
(10) Pub. No.: US 2014/0332670 A1
(43) Pub. Date: Nov. 13, 2014

(54) PHOTODETECTING CIRCUIT, OPTICAL RECEIVER, AND PHOTOCURRENT MEASUREMENT METHOD FOR PHOTO DETECTOR

(71) Applicant: Sumitomo Electric Industries, Ltd., Osaka-shi (JP)

(72) Inventor: Yoshihiro Tateiwa, Yokohama-shi (JP)

(73) Assignee: Sumitomo Electric Industries, Ltd., Osaka-shi (JP)

(21) Appl. No.: 14/273,333

(22) Filed: May 8, 2014

(30) Foreign Application Priority Data
May 10, 2013 (JP) 2013-100339

(51) Int. Cl. H03F 3/08

(52) U.S. Cl. CPC H03F 3/08
USPC 250/208.2

(57) ABSTRACT

The present invention is a photodetecting circuit comprising a plurality of operational amplifiers provided so as to correspond to respective photo detectors disposed on a common semiconductor substrate, each operational amplifier having an inverting input terminal connected to a cathode of the photo detector and a non-inverting input terminal supplied with a voltage to be applied to the photo detector; a plurality of resistances connected between output terminals and inverting input terminals of the respective operational amplifiers; and a terminal, disposed on at least the inverting input terminal side in both ends of the resistance, for connecting with a meter for measuring a photocurrent of the photo detector.

### BACKGROUND OF THE INVENTION

1. Field of the Invention

The present invention relates to a photodetecting circuit, an optical receiver, and a photocurrent measurement method for a photo detector.

2. Related Background Art

Coherent optical communication systems have been known as high-speed, large-capacity optical communication systems. In an example of optical receivers used in the coherent optical communication systems, signal light and local oscillation light (LO light) are split, delayed, and combined by a 90° hybrid coupler, so as to demodulate a phase-modulated signal, and then a photo detector converts an optical signal to an electric signal.

Operations of 90° hybrid couplers are important for correctly demodulating the phase-modulated signal. Therefore, methods for evaluating phase characteristics of 90° hybrid couplers have been proposed. For example, there has been proposed a method for evaluating phase characteristics of a 90° hybrid coupler by measuring respective photocurrents of a plurality of photo detectors disposed downstream of the 90° hybrid coupler (see, for example, Non Patent Literature 1).

### CITATION LIST

### Non Patent Literature

Non Patent Literature 1: TATEIWA Yoshihiro, et al., “A Study on Data Processing in 90° Hybrid Phase Error Analysis,” Proceedings of the 2011 Society Conference of IEICE (2), B-10-57, p. 270, 2011.

### SUMMARY OF THE INVENTION

### Technical Problem

Any leak current flowing between photo detectors at the time of measuring the respective photocurrents of a plurality of photo detectors makes it hard to measure the photocurrents accurately. It is an object of the present invention to provide a photodetecting circuit, an optical receiver, and a photocurrent measurement method for a photo detector, which can accurately measure a photocurrent of a photo detector.

### Solution to Problem

One aspect of the present invention provides a photodetecting circuit comprising a plurality of operational amplifiers provided so as to correspond to respective photo detectors disposed on a common semiconductor substrate, each operational amplifier having an inverting input terminal connected to a cathode of the photo detector and a non-inverting input terminal supplied with a voltage to be applied to the photo detector; a plurality of resistances connected between output terminals and inverting input terminals of the respective operational amplifiers; and a terminal, disposed on at least the inverting input terminal side in both ends of the resistance, for connecting with a meter for measuring a photocurrent of the photo detector.

Another aspect of the present invention provides an optical receiver comprising the photodetecting circuits mentioned above, and the plurality of photo detectors having cathodes connected to the respective inverting input terminals of the plurality of operational amplifiers.

Another aspect of the present invention provides a photocurrent measurement method for a photo detector, the method comprising the steps of connecting a plurality of operational amplifiers to respective photo detectors disposed on a common semiconductor substrate, the operational amplifiers having inverting input terminals connected to cathodes of the photo detectors and non-inverting input terminals supplied with a voltage to be applied to the photo detectors; and measuring currents flowing through connection lines connecting the inverting input terminals and output terminals of the respective operational amplifiers in a state where an optical signal is fed to the photo detectors, so as to determine photocurrents of the photo detectors.

### BRIEF DESCRIPTION OF THE DRAWINGS

FIG. 1 is a block diagram illustrating an evaluation system in accordance with Comparative Example 1;

FIG. 2 is a sectional view illustrating a structure of two photo detectors included in one balanced receiver;

FIG. 3(a) is a circuit diagram illustrating connections between a power supply and two photo detectors included in one balanced receiver, while FIG. 3(b) is a chart illustrating an example of currents measured by oscilloscopes;

FIG. 4 is a circuit diagram illustrating a state where a leak current is generated between cathodes of the photo detectors;

FIG. 5 is a circuit diagram illustrating a photodetecting circuit in accordance with Example 1;

FIG. 6 is a flowchart illustrating a method for measuring photocurrents of photo detectors;

FIG. 7 is a top view illustrating an optical receiver in accordance with Example 2;

FIG. 8 is a circuit diagram illustrating a photodetecting circuit of a balanced receiver in the optical receiver of Example 2; and

FIG. 9 is a circuit diagram illustrating a photodetecting circuit of a balanced receiver in an optical receiver of Example 3.

### DESCRIPTION OF THE PREFERRED EMBODIMENTS

One aspect of the present invention provides a photodetecting circuit comprising a plurality of operational amplifiers provided so as to correspond to respective photo detectors disposed on a common semiconductor substrate, each operational amplifier having an inverting input terminal connected to a cathode of the photo detector and a non-inverting input terminal supplied with a voltage to be applied to the photo detector; a plurality of resistances connected between output terminals and inverting input terminals of the respective operational amplifiers; and a terminal, disposed on at least the inverting input terminal side in both ends of the resistance, for connecting with a meter for measuring a photocurrent of the photo detector. This makes it possible to measure photocurrents of the photo detectors accurately.

In the structure mentioned above, the terminal for connecting with the meter for measuring the photocurrent of the photo detector may be disposed on at least the inverting input terminal side in both ends of each of the plurality of resistances.

In the above-mentioned structure, phases of light received by the plurality of photo detectors may be shifted from each other.

In the above-mentioned structure, the voltage in common may be supplied to the respective non-inverting input terminals of the plurality of operational amplifiers.

Another aspect of the present invention provides an optical receiver comprising any of the photodetecting circuits mentioned above, and the plurality of photo detectors having cathodes connected to the respective inverting input terminals of the plurality of operational amplifiers. This makes it possible to measure photocurrents of the photo detectors accurately.

The structure mentioned above may further comprise a 90° hybrid coupler for receiving signal light and local oscillation light and emitting interference light formed by the signal light and local oscillation light interfering with each other, while the photo detectors may receive the interference light emitted from the 90° hybrid coupler.

The above-mentioned structure may further comprise a transimpedance amplifier connected to an anode of the photo detector.

In the above-mentioned structure, the transimpedance amplifier may comprise two input terminals, the two input terminals receiving respective photocurrents issued from two of the photo detector.

Another aspect of the present invention provides a photocurrent measurement method for a photo detector, the method comprising the steps of connecting a plurality of operational amplifiers to respective photo detectors disposed on a common semiconductor substrate, the operational amplifiers having inverting input terminals connected to cathodes of the photo detectors and non-inverting input terminals supplied with a voltage to be applied to the photo detectors; and measuring currents flowing through connection lines connecting the inverting input terminals and output terminals of the respective operational amplifiers in a state where an optical signal is fed to the photo detectors, so as to determine photocurrents of the photo detectors. This makes it possible to measure photocurrents of the photo detectors accurately.

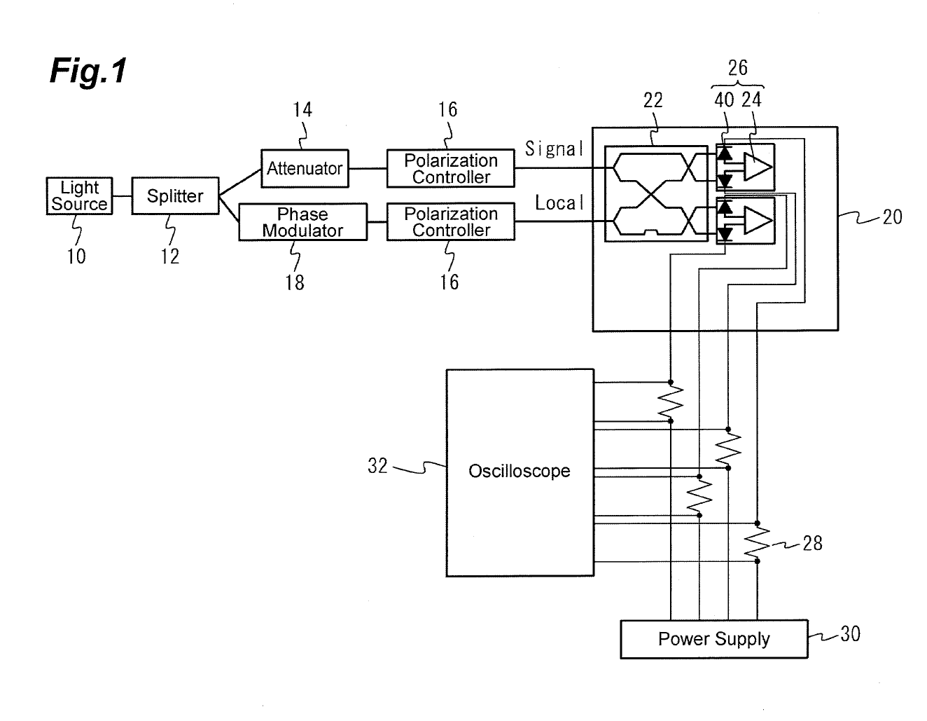

First, an evaluation system for evaluating phase characteristics of a 90° hybrid coupler will be explained. FIG. 1 is a block diagram illustrating the evaluation system in accordance with Comparative Example 1. As in FIG. 1, CW light (continuous wave light) emitted from a light source 10 is split by a splitter 12 into two branches. One branch of light passes through an attenuator 14 and a polarization controller 16, so as to enter an optical receiver 20. The other branch of light passes through a phase modulator 18 and a polarization controller 16, so as to enter the optical receiver 20. The other branch of light is subjected to low-frequency phase modulation by the phase modulator 18. Here, the phase-modulated branch of light and the branch of light not subjected to the phase modulation are used as local oscillation light (LO light) and signal light, respectively.

The optical receiver 20 comprises a 90° hybrid coupler 22 and two balanced receivers 26 each including two photo detectors 40 and one transimpedance amplifier (TIA) 24. In each balanced receiver 26, the anodes of two photo detectors 40 are connected to one TIA 24. A common power supply 30 is connected to the cathodes of the four photo detectors 40 included in the two balanced receivers 26. Four resistances 28 are connected between the power supply 30 and the respective photo detectors 40. As will be explained later in detail, the photocurrent generated in each photo detector 40 is determined by a change in potential measured between both ends of its corresponding resistance 28.

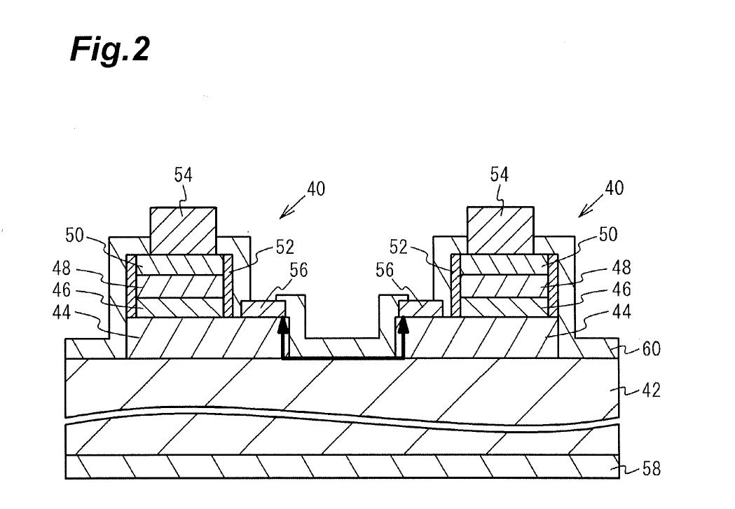

The photo detectors will now be explained. FIG. 2 is a sectional view illustrating a structure of two photo detectors included in one balanced receiver. As in FIG. 2, two photo detectors 40 are integrated on a common semiconductor substrate 42. An example of the semiconductor substrate 42 is an InP substrate. In each photo detector 40, an n-type semiconductor layer 44, a light-absorbing layer 46, and a p-type semiconductor layer 48 are stacked in sequence on the semiconductor substrate 42. For example, the n-type semiconductor layer 44, light-absorbing layer 46, and p-type semiconductor layer 48 are n-type InP, nondoped InGAs, and p-type InP layers, respectively. A contact layer 50 made of a p-type InGaAs layer, for example, is disposed on the p-type semiconductor layer 48. A passivation film 52 made of an InP film, for example, is provided on side faces of the light-absorbing layer 46, p-type semiconductor layer 48, and contact layer 50.

A p-electrode 54 which is an ohmic electrode is disposed on the contact layer 50, while an n-electrode 56 which is an ohmic electrode is disposed on the n-type semiconductor layer 44. An example of the p-electrode 54 is a metal layer in which Pt, Ti, Pt, and Au are stacked in sequence from the contact layer 50 side, while an example of the n-electrode 56 is an AuGeNi layer. A rear metal layer 58 made of Au, for example, is disposed under the semiconductor substrate 42. An insulating film 60 made of an SiN film, for example, is provided so as to expose the upper faces of the p-electrode 54 and n-electrode 56 while covering the other regions.

While FIG. 2 illustrates an example in which two photo detectors 40 included in one balanced receiver 26 are integrated on the same semiconductor substrate 42, four photo detectors 40 included in two balanced receivers 26 may be integrated on the same semiconductor substrate 42. That is, a plurality of photo detectors 40 may be integrated on the common semiconductor substrate 42.

Returning to FIG. 1, in the 90° hybrid coupler 22, the signal light and local oscillation light incident on the optical receiver 20 are spectrally resolved, combined, and delayed in an optical waveguide therewithin, and interference light is emitted from four ports. The interference light is emitted from the four ports as four optical signals separated into positive and negative in- and quadrature-phase components. The photo detectors 40 receive the interference light emitted from the 90° hybrid coupler 22 and generate photocurrents by photoelectric conversion. The two photo detectors 40 included in one balanced receiver 26 receive the positive and negative components of the same phase component. That is, when one of the two photo detectors receives the positive in-phase component of the interference light, the other receives the negative in-phase component of the interference light. When one of the two photo detectors 40 receives the positive quadrature-phase component of the interference light, the other receives the negative quadrature-phase component of the interference light. Thus, the phases of interference light received by the two photo detectors 40 included in one balanced receiver 26 are shifted from each other by 180°.

The evaluation system of Comparative Example 1 determines the photocurrent generated by each photo detector 40 by measuring a change in potential between both ends of its corresponding resistance 28 with an oscilloscope 32. This can evaluate phase characteristics of the respective photocurrents of the photo detectors 40 and consequently those of the 90° hybrid coupler 22. However, there are cases where such a structure is hard to measure the photocurrents of the photo detectors 40 accurately. A reason therefore will be explained in the following.

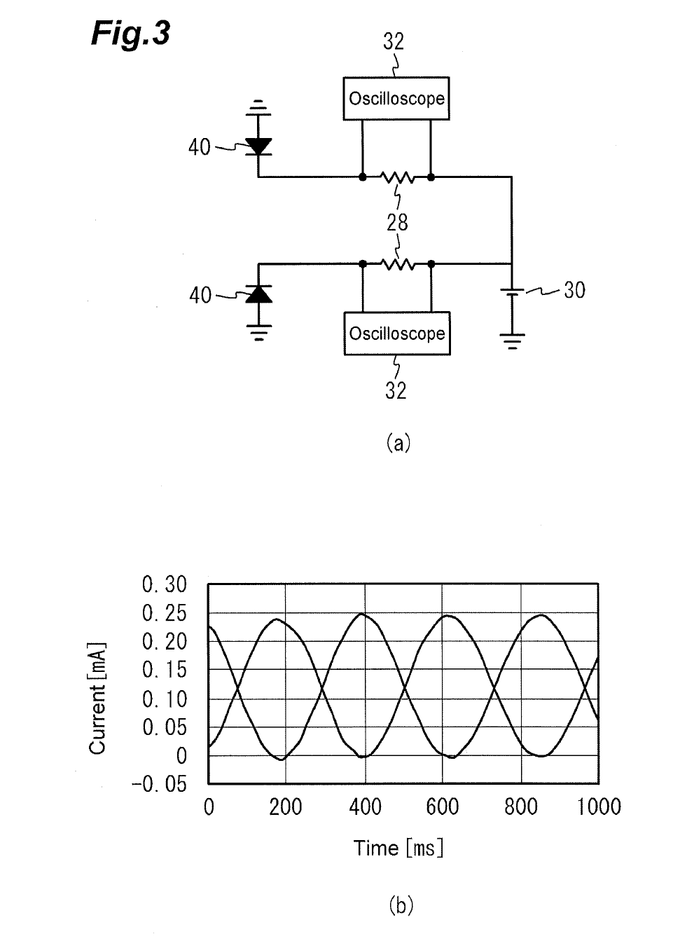

FIG. 3(a) is a circuit diagram illustrating connections between a power supply and two photo detectors included in one balanced receiver, while FIG. 3(b) is a chart illustrating an example of currents measured by oscilloscopes. As in FIG. 3(a), the power supply 30 is connected to the cathodes of the two photo detectors 40 through the respective resistances 28. The oscilloscopes 32 for measuring the photocurrents generated in the photo detectors 40 are connected to both ends of their corresponding resistances 28. As in FIG. 3(b), the currents measured by the oscilloscopes 32 are shifted from each other by 180°. This is because the two photo detectors 40 included in one balanced receiver 26 receive the optical signals of the positive and negative components of the same phase component as mentioned above.

The photocurrent generated by the photo detector 40 varies as the interference light (optical signal) entering there changes, whereby the voltage applied to the cathode of each photo detector 40 fluctuates because of a voltage drop in the resistance 28 and fails to become constant. Here, as in FIG. 3(b), the respective photocurrents generated in the photo detectors 40 have phases shifted from each other, thereby yielding a potential difference between the cathodes of the photo detectors 40. When a potential difference is generated between the cathodes (n-electrodes 56) of the photo detectors 40 in the case where a plurality of photo detectors 40 are integrated on the common semiconductor substrate 42 as in FIG. 2, a leak current (indicated by arrows in FIG. 2) may occur through the semiconductor substrate 42 between the n-electrodes 56. This leak current is likely to occur when the semiconductor substrate 42 has low resistance.

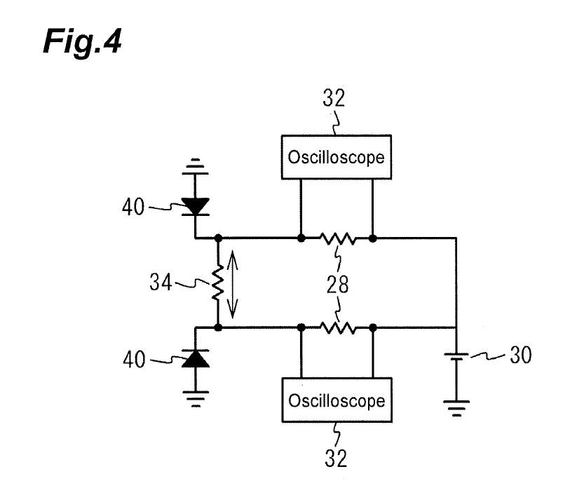

FIG. 4 is a circuit diagram illustrating a state where a leak current is generated between the cathodes of the photo detectors 40. As in FIG. 4, when the resistance 34 of the semiconductor substrate 42 is not high enough, a leak current (indicated by arrows in FIG. 4) may occur between the cathodes of the photo detectors 40, whereby the oscilloscopes 32 may measure currents in which the leak current is added to the photocurrents of the photo detectors 40. This makes it hard to measure the photocurrents of the photo detectors 40 accurately.

Therefore, in the following, examples which can accurately measure photocurrents of photo detectors will be explained.

### Example 1

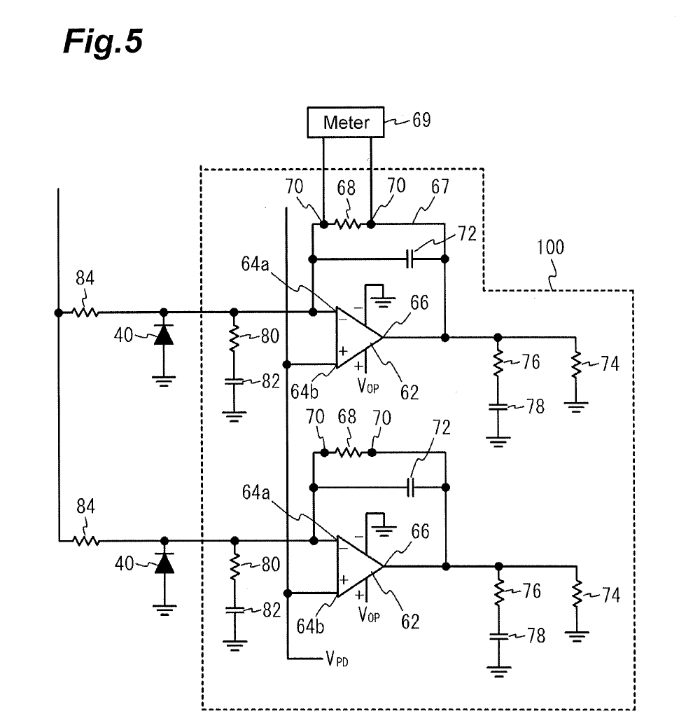

FIG. 5 is a circuit diagram illustrating a photodetecting circuit in accordance with Example 1. FIG. 5 represents a photodetecting circuit connected to two photo detectors included in one balanced receiver by way of example. As in FIG. 5, a photodetecting circuit 100 of Example 1 has operational amplifiers 62 connected to the photo detectors 40. The photo detectors 40 are disposed on the same semiconductor substrate 42 as explained in FIG. 2. In two input terminals of each operational amplifier 62, an inverting input terminal 64a is connected to the cathode of its corresponding photo detector 40. A non-inverting input terminal 64b of the operational amplifier 62 is supplied with a voltage V_{PD} to be applied to the photo detector 40. An output terminal 66 of the operational amplifier 62 and the non-inverting input terminal 64a are connected to each other with a connection line 67 which is a lead, for example, while the connection line 67 contains a resistance 68 connected thereto. This forms a non-inverting amplifier circuit. Both ends of the resistance 68 are provided with terminals 70 for connecting with a meter 69 (e.g., oscilloscope) for measuring the photocurrent generated by the photo detector 40. The meter 69 for measuring the photocurrent generated by the photo detector 40 depicted on the lower side in FIG. 5 is omitted for clarification of the diagram.

A capacitor 72 is connected in parallel with the resistance 68. A terminating resistance 74 is connected between the output terminal 66 of the operational amplifier 62 and the ground. A resistance 76 and a capacitor 78 are connected in series between a terminal between the output terminal 66 and the terminating resistance 74 and the ground. A resistance 80 and a capacitor 82 are connected in series between a terminal between the inverting input terminal 64a of the operational amplifier 62 and the photo detector 40 and the ground. A resistance 84 which is connected to the cathode of the photo detector 40 represents a resistance existing between the respective n-electrodes 56 of the photo detectors 40 in FIG. 2.

Thus, in the photodetecting circuit 100 of Example 1, a plurality of operational amplifiers 62 are provided so as to correspond to the respective photo detectors 40 disposed on the common semiconductor substrate 42, while each operational amplifier 62 has the inverting input terminal 64a connected to the cathode of its corresponding photo detector 40 and the non-inverting input terminal 64b supplied with the voltage V_{PD} to be applied to the photo detector 40. A plurality of resistances 68 are connected between the output terminals 66 and inverting input terminals 64a of the respective operational amplifiers 62, while the terminals 70 for connecting with the meter 69 for measuring the photocurrent generated in the photo detector 40 are disposed at both ends of each resistance 68. In such a structure, negative feedback is applied from the output terminal 66 to the inverting input terminal 64a, so as to control the voltage fed to the inverting input terminal 64a such that it has the same level as with the voltage fed to the non-inverting input terminal 64b. Therefore, even when the photocurrent generated by the photo detector 40 varies its level, the voltage applied to the cathode of the photo detector 40 can be controlled such as to have the same level as with the voltage V_{PD} supplied to the non-inverting input terminal 64b. This can inhibit potential differences from occurring between the respective cathodes of the photo detectors 40 and suppress the leak current between the photo detectors 40. Hence, the photocurrents of the photo detectors 40 can be measured accurately.

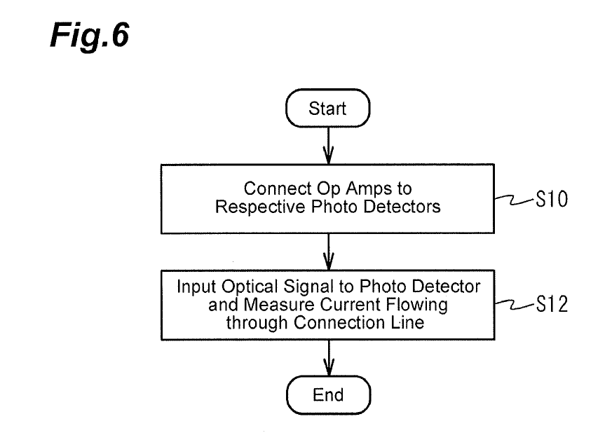

FIG. 6 is a flowchart illustrating a method for measuring photocurrents of photo detectors. The photocurrent measurement method for photo detectors will be explained by using FIG. 6 while referring to FIG. 5. As in FIG. 6, a plurality of operational amplifiers 62 are connected to the respective photo detectors 40 disposed on the common semiconductor substrate 42 such as to have the inverting input terminals 64a connected to the cathodes of the photo detectors 40 and the non-inverting input terminals 64b supplied with a voltage to be applied to the photo detectors 40 (step S10). Then, in a state where an optical signal is fed to the photo detectors 40, currents flowing through the connection lines 67 connecting the inverting input terminals 64a and output terminals 66 of the respective operational amplifiers 62 are measured (step S12). For example, the potential difference between both ends of each resistance 68 may be measured by the meter 69, so as to determine the current flowing through the connection line 67, or other methods may determine the current flowing through the connection line 67. As a consequence, photocurrents generated by the photo detectors 40 can be measured accurately.

When the phases of light received by a plurality of photo detectors 40 are shifted from each other, a leak current is likely to occur between the photo detectors 40. Therefore, in such a case, it is preferred for the operational amplifier 62 and the resistance 68 to be connected to each of the plurality of photo detectors 40 as in FIG. 5.

For inhibiting potential differences from occurring between the respective cathodes of the photo detectors 40 and suppressing the leak current between the photo detectors 40, it is preferred for the non-inverting input terminals 64b of a plurality of operational amplifiers 62 connected to the respective photo detectors 40 to be supplied with the common voltage V_{PD} as in FIG. 5.

Preferably, the terminals 70 are disposed at both ends of each of the plurality of resistances 68 connected between the output terminals 66 and inverting input terminals 64a of the respective operational amplifiers 62 as in FIG. 5. As a consequence, the respective photocurrents of the plurality of photo detectors 40 can be measured accurately.

Preferably, as in FIG. 5, the capacitor 72 is connected in parallel with the resistance 68, the resistance 76 and capacitor 78 are connected in series between the terminal between the output terminal 66 of the operational amplifier 62 and the terminating resistance 74 and the ground, and the resistance 80 and capacitor 82 are connected in series between the terminal between the inverting input terminal 64a and the photo detector 40 and the ground. This can inhibit the operational amplifier 62 from oscillating upon switching. For example, in the case where an operational amplifier which is likely to oscillate at about several MHz is employed as the operational amplifier 62, it can be inhibited from oscillating when the capacitor 72 having a capacity of 10 nF, the resistances 76, 80 each having a resistance value of 100Ω, and the capacitors 78, 82 each having a capacity of 1 μF are used.

### Example 2

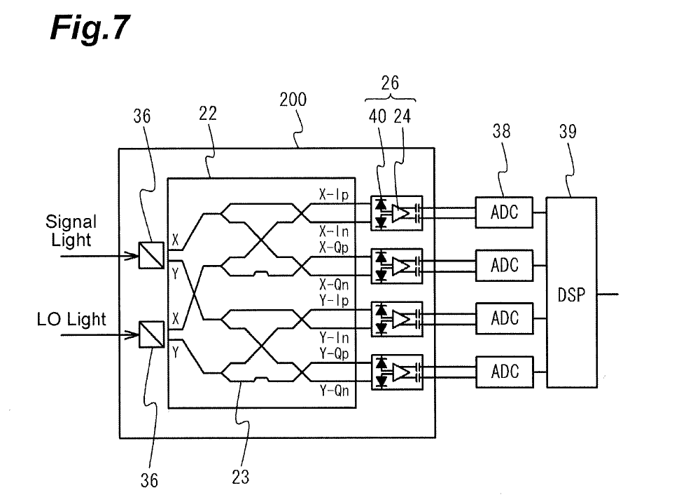

FIG. 7 is a top view illustrating an optical receiver in accordance with Example 2. An example of the optical receiver is a coherent optical receiver. As in FIG. 7, an optical receiver 200 of Example 2 comprises polarization beam splitters (PBS) 36, a 90° hybrid coupler 22 constituted by a planar lightwave circuit (PLC), for example, and a plurality of balanced receivers 26 each including two photo detectors 40 and one TIA 24.

The polarization beam splitters 36 separate each of signal light and local oscillation light (LO light) incident on the optical receiver 20 into X- and Y-polarized waves orthogonal to each other. TE-polarized light and TM-polarized light may be used as the X- and Y-polarized waves, respectively, and vice versa.

In the 90° hybrid coupler 22, the signal light and local oscillation light each separated into the X- and Y-polarized waves by the polarization beam splitters 36 are spectrally resolved, combined, and delayed in the optical waveguide 23 therewithin, so as to emit interference light. For example, the X-polarized wave of the signal light is combined with the X-polarized wave of the local oscillation light, and then thus combined waves are separated into positive and negative in- and quadrature-phase components, which are emitted as four optical signals (X-Ip, X-In, X-Qp, X-Qn). Similarly, the Y-polarized wave of the signal light is combined with the Y-polarized wave of the local oscillation light, and then thus combined waves are separated into positive and negative in- and quadrature-phase components, which are emitted as four optical signals (Y-Ip, Y-In, Y-Qp, Y-Qn).

The photo detectors 40 receive the interference light emitted from the 90° hybrid coupler 22 and generate photocurrents by photoelectric conversion. An example of the photo detectors 40 is a photodiode (PD). At least a part of a plurality of photo detectors 40 provided in the optical receiver 200 are integrated on a common semiconductor substrate 42 as in FIG. 2. The two photo detectors 40 included in one balanced receiver 26 receive the positive and negative components of the same phase component of the optical signal. Each TIA 24 converts a pair of photocurrents issued from two photo detectors 40 into a voltage signal and amplifies it. The electric signal amplified by the TIA 24 is let out of the optical receiver 200.

The electric signals let out of the optical receiver 200 are converted into digital signals by analog-to-digital converters (ADC) 38. A digital signal processing circuit (DSP) 39 subjects the converted digital signals to various kinds of signal processing including signal demodulation.

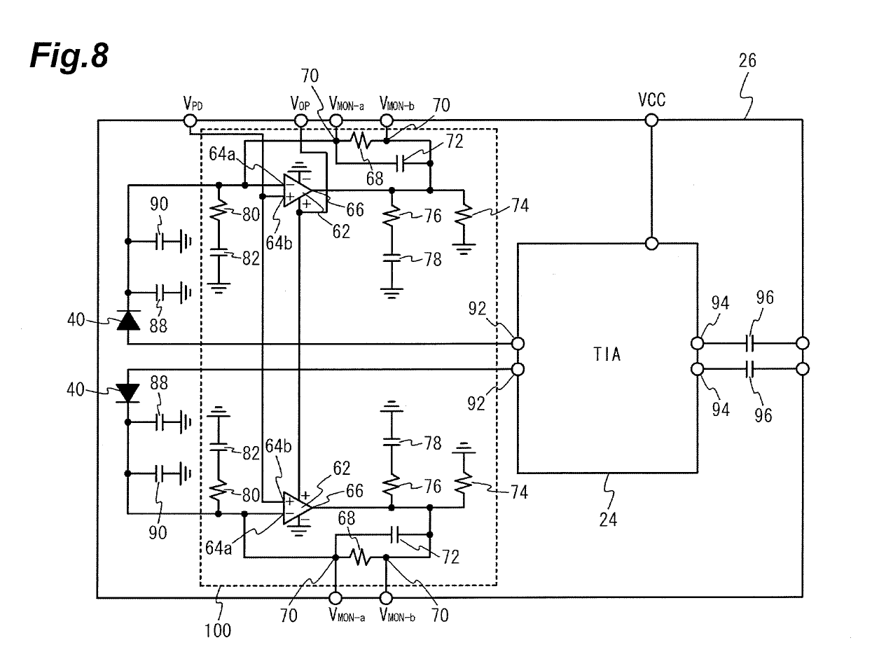

FIG. 8 is a circuit diagram illustrating the balanced receiver in the optical receiver of Example 2. As in FIG. 8, the balanced receiver 26 in the optical receiver 200 of Example 2 has the photodetecting circuit 100 of Example 1 illustrated in FIG. 5, the photo detectors 40 having their cathodes connected to the respective inverting input terminals 64a of the operational amplifiers 62 included in the photodetecting circuit 100, and the TIA 24 connected to the anodes of the photo detectors 40. Capacitors 88, 90 are connected to the cathode of each photo detector 40.

In order to convert a pair of photocurrents issued from the two photo detectors 40 into a voltage signal and amplify it as mentioned above, the TIA 24 has two input terminals 92 and two output terminals 94. That is, the photocurrents issued from two photo detectors 40 are fed into the two input terminals 40, respectively. A capacitor 96 is connected downstream of each output terminal 94 of the TIA 24.

As explained in Example 1, a meter (e.g., oscilloscope) for measuring the photocurrent generated by the photo detector 40 is connected to the terminals 70 disposed at both ends of each resistance 68. The meter is not depicted. The photocurrent of the photo detector 40 is determined by using the meter to measure a difference between V_{MON-a} and V_{MON-b} which are potentials at both ends of the resistance 68, for example.

Example 2 comprises the photodetecting circuit 100 of Example 1 and a plurality of photo detectors 40, disposed on the common semiconductor substrate 42, having their cathodes connected to the respective inverting input terminals 64a of a plurality of operational amplifiers 62 included in the photodetecting circuit 100. This can suppress leak currents between the photo detectors 40 and make it possible to measure the photocurrents of the photo detectors 40 accurately as with Example 1.

As in FIG. 7, the optical receiver 200 of Example 2 comprises the 90° hybrid coupler 22 for receiving the signal light and local oscillation light (LO light) and emitting interference light formed by the signal light and local oscillation light interfering with each other. The photo detectors 40 receive the interference light emitted from the 90° hybrid coupler 22. In such a structure, the phases of light received by a plurality of photo detectors 40 are shifted from each other. Therefore, leak currents are likely to occur between the photo detectors 40, thus making it preferable for the operational amplifier 62 and resistance 68 to be connected to each of the plurality of photo detectors 40 as in FIG. 8.

When two photo detectors 40 included in one balanced receiver 26 operate normally, the photocurrents fed into the TIA 24 have DC components substantially equal to each other. When the photocurrents issued from the two photo detectors 40 lose their balance, however, the TIA 24 fails to perform signal processing normally. It is therefore preferable for the optical receiver 200 to monitor the photocurrents issued from the two photo detectors 40 and raises an alarm when the balance is lost.

### Example 3

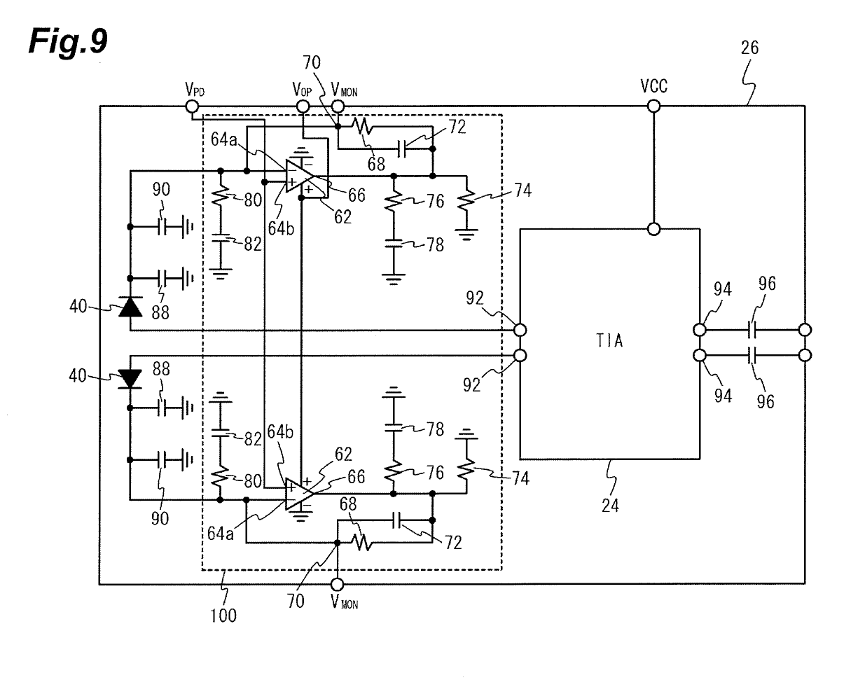

The optical receiver in accordance with Example 3 is the same as that of Example 2 in FIG. 7 and thus will not be explained. FIG. 9 is a circuit diagram illustrating a balanced receiver in the optical receiver of Example 3. As in FIG. 9, it differs from Example 2 of FIG. 8 in that the terminal 70 for connecting with the meter for measuring the photocurrent of the photo detector 40 is provided on only the photo detector 40 side of the resistance 68 instead of both ends thereof. Except for this point, the structure is the same as Example 2 in FIG. 8 and thus will not be explained.

When the terminal 70 for connecting with the meter for measuring the photocurrent of the photo detector 40 is provided on at least the inverting input terminal 64a side in both ends of the resistance 68 as in Example 3, the photocurrent of the photo detector 40 can be determined by measuring a change in potential between V_{MON} and the ground with the meter, for example.

While examples of the present invention are explained in detail in the foregoing, the present invention is not limited to such specific examples but can be modified and altered in various ways within the scope of the gist of the invention set forth in the claims.

What is claimed is:

1. A photodetecting circuit comprising:
a plurality of operational amplifiers provided so as to correspond to respective photo detectors disposed on a common semiconductor substrate, each operational amplifier having an inverting input terminal connected to a cathode of the photo detector and a non-inverting input terminal supplied with a voltage to be applied to the photo detector;
a plurality of resistances connected between output terminals and inverting input terminals of the respective operational amplifiers; and
a terminal, disposed on at least the inverting input terminal side in both ends of the resistance, for connecting with a meter for measuring a photocurrent of the photo detector.

2. A photodetecting circuit according to claim 1, wherein the terminal for connecting with the meter for measuring the photocurrent of the photo detector is disposed on at least the inverting input terminal side in both ends of each of the plurality of resistances.

3. A photodetecting circuit according to claim 1, wherein phases of light received by the plurality of photo detectors are shifted from each other.

4. A photodetecting circuit according to claim 1, wherein the voltage in common is supplied to the respective non-inverting input terminals of the plurality of operational amplifiers.

5. An optical receiver comprising the photodetecting circuit according to claim 1; and
the plurality of photo detectors having cathodes connected to the respective inverting input terminals of the plurality of operational amplifiers.

6. An optical receiver according to claim 5, further comprising a 90° hybrid coupler for receiving signal light and local oscillation light and emitting interference light formed by the signal light and local oscillation light interfering with each other;
wherein the photo detectors receive the interference light emitted from the 90° hybrid coupler.

7. An optical receiver according to claim 5, further comprising a transimpedance amplifier connected to an anode of the photo detector.

8. An optical receiver according to claim 7, wherein the transimpedance amplifier comprises two input terminals; and
wherein the two input terminals receive respective photocurrents issued from two of the photo detectors.

9. A photocurrent measurement method for a photo detector, the method comprising the steps of:
connecting a plurality of operational amplifiers to respective photo detectors disposed on a common semiconductor substrate, the operational amplifiers having inverting input terminals connected to cathodes of the photo detectors and non-inverting input terminals supplied with a voltage to be applied to the photo detectors; and
measuring currents flowing through connection lines connecting the inverting input terminals and output terminals of the respective operational amplifiers in a state where an optical signal is fed to the photo detectors, so as to determine photocurrents of the photo detectors.
